(19) United States
(12) Patent Application Publication
(10) Pub. No.: US 2009/0071818 A1
(43) Pub. Date: Mar. 19, 2009

(54) FILM DEPOSITION APPARATUS AND METHOD OF FILM DEPOSITION

(75) Inventors: Yoichi Fukumiya, Yokohama-shi (JP); Tatsumi Shoji, Yokohama-shi (JP); Tetsuro Saito, Isehara-shi (JP); Koji Kitani, Chofu-shi (JP); Satoshi Nakamura, Machida-shi (JP); Koh Kamachi, Kawasaki-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 12/293,259

(22) PCT Filed: Mar. 15, 2007
(86) PCT No.: PCT/JP07/55928

§ 371 Date: Sep. 16, 2008

(30) Foreign Application Priority Data
Mar. 17, 2006 (JP) 2006-074515
Feb. 28, 2007 (JP) 2007-049179

(51) Int. Cl. C23C 14/34; C23C 14/56

(52) U.S. Cl. 204/192.11; 204/298.04

(57) ABSTRACT

An ion beam sputtering film deposition apparatus is provided which can form a high-quality thin film that is dense, smooth and faultless. The film deposition apparatus has ion beam irradiating unit, a target 105 containing a film forming substance to be sputtered, and holding unit 112 to hold a substrate 106 on which the sputtered film forming substance is deposited. The ion beam irradiating unit irradiates gas cluster ions to both the target 105 and the substrate 106.

### TECHNICAL FIELD

The present invention relates to a film deposition apparatus utilizing gas cluster ions beam and a method of film deposition using the apparatus.

### BACKGROUND ART

Conventionally, sputtering apparatuses are generally used as film deposition apparatuses, and Japanese Patent Application Laid-Open No. 2001-181836 describes an ion beam sputtering apparatus. This is an ion beam sputtering apparatus in which particles sputtered out from a target are deposited as a film on a substrate surface and in which an ion separator to select only an ion beam having a specific energy intervenes in-between.

Japanese Patent Application Laid-Open No. S50-105550 describes a method in which a target containing a film forming substance is sputtered by a cluster ion beam, and the sputtered substance is formed as a film on a substrate.

Herein, “cluster ion” is obtained by ionizing a cluster, which is generated by cooling a gas by thermal expansion through a nozzle, by electron impact, etc. (See Document: 0. F. Hagena, W. Obert, Jour. Chem. Phys. 56, 5 (1972) 1793). According to the ion beam sputtering apparatus described in the Japanese Patent Application Laid-Open No. 2001-181836, since the sputtering ratio is low and the film depositing rate is low, and not only divalent but also monovalent monomer ions have a high speed and high energy, the apparatus has a problem of causing damage to a formed thin film.

In the method of thin film deposition described in the Japanese Patent Application Laid-Open No. S50-105550, since many of particles sputtered from a target by cluster ions have a larger size than particles by monomer ions, voids are liable to occur when the particles are deposited on a substrate. Therefore, the denseness is liable to become low and the surface smoothness is sometimes deteriorated.

Therefore, it is the object of the present invention to provide an ion beam sputtering apparatus whereby a high-quality thin film that is dense, smooth and faultless is formed at a fast rate, and a method of film deposition using the same.

### DISCLOSURE OF THE INVENTION

In consideration of the above-mentioned problems, the film deposition apparatus provided by the present invention is characterized by comprising first holding unit to hold a target containing a film forming substance, second holding unit to hold a substrate on which the film forming substance is deposited, and ion beam irradiation unit to irradiate gas cluster ions to each of the target and the substrate.

The method of film deposition provided by the present invention is a method of film deposition to form a film on a substrate surface by irradiating sputtered particles generated by sputtering a target to the substrate surface, and is characterized by depositing on the substrate the sputtered particles generated by the irradiation of gas cluster ions to the target and irradiating the gas cluster ions to the substrate.

In the present invention constituted as described above, clusters are arranged to be irradiated to a target and a substrate. Therefore, a high-quality thin film that is dense, smooth and faultless can be formed. That is, the fast film deposition and the high-quality film deposition can simultaneously be achieved.

Further features of the present invention will become apparent from the following description of exemplary embodiments with reference to the attached drawings.

### BRIEF DESCRIPTION OF THE DRAWINGS

FIG. 1 is a view illustrating a configuration of a film deposition apparatus according to a first embodiment of the present invention;

FIG. 2 is a view illustrating a configuration of a film deposition apparatus according to a second embodiment of the present invention;

FIG. 3 is a view illustrating a configuration of a film deposition apparatus according to a third embodiment of the present invention;

FIG. 4 is a view illustrating a configuration of a film deposition apparatus according to a fourth embodiment of the present invention;

FIG. 5 is a view illustrating a configuration of a film deposition apparatus according to a fifth embodiment of the present invention;

FIG. 6 is a view illustrating a configuration of a film deposition apparatus according to a sixth embodiment of the present invention;

FIG. 7 is a view illustrating a configuration of a film deposition apparatus according to a seventh embodiment of the present invention; and

FIG. 8 is a view illustrating a configuration of a film deposition apparatus according to an eighth embodiment of the present invention.

### BEST MODE FOR CARRYING OUT THE INVENTION

Hereinafter, the embodiments of the present invention will be in detail described referring to the drawings.

### First Embodiment

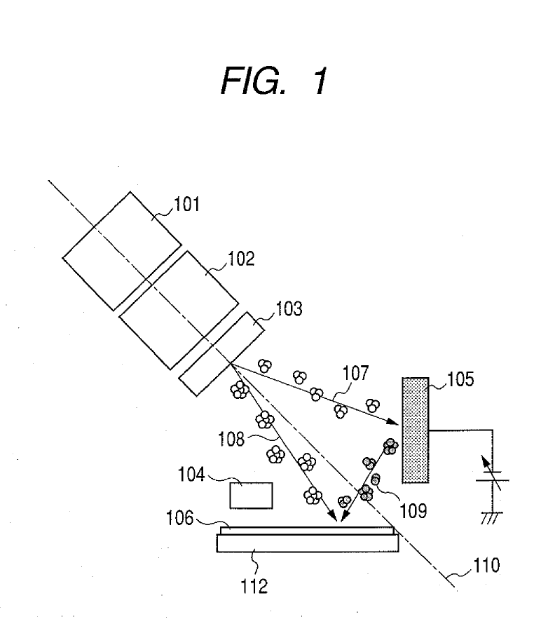

A film deposition apparatus of the first embodiment has, as shown in FIG. 1, ion beam irradiation unit composed of a gas cluster ion source 101, a set of electrodes for extraction, acceleration and focusing 102, and mass separation unit 103.

It also has a neutralizer 104, a target 105 provided with a bias voltage impression mechanism and a substrate 106. The set of electrodes 102 extracts gas cluster ions from the gas cluster ion source 101, and accelerates the ions to a predetermined direction. Herein, “gas cluster ion” is obtained by ionizing a cluster, which is generated by ejecting high pressure gas into vacuum through a nozzle and cooling a gas by thermal expansion, by electron impact, etc. The “gas cluster ion source” is an apparatus in which gas cluster ions are generated.

The mass separation unit 103 deflects the trajectories of the gas cluster ions according to the masses of the ions by imparting a predetermined electric and magnetic fields to the gas cluster ion beam. In the embodiment, a transverse field mass separator is used as mass separating unit. Since the transverse electromagnetic fields mass separator does not bend the beam line, it can be made to be one having a relatively small apparatus volume. Further, even if the mass and the energy of gas cluster ions enter the mass separator change, only alteration of the intensities of electric and magnetic fields can perform a desired deflection. However, the mass separation unit is not limited to this, but may be any of permanent magnetic, electromagnetic, and transverse field mass separators. The mass separation unit is an apparatus to deflect the trajectories of gas cluster ions according to the mass thereof and to pass only gas cluster ions having a mass of not less than a desired one through. The mass separation unit removes particles having a high speed and high energy out of particles reflecting from the target and directly incident to the substrate. For example, particles having a size of not more than 10 atoms (or 10 molecules) per cluster are removed. These mass separation unit can be optionally combined.

The neutralizer 104 is constituted of a heat filament, a hollow cathode, etc., and neutralizes the surface of the substrate to be irradiated with gas cluster ions by irradiating electrons to the substrate. In the embodiment, a configuration in which electrons are irradiated only to the substrate is described, but a similar configuration can be used also for the target. Since the charge-up of the substrate and the target can be prevented, variation in the amount of clusters incident to the substrate and the target can be suppressed.

The target 105 is arranged to be held by holding unit not shown in the figure. The substrate 106 is arranged to be held by holding unit 112. The target 105 contains a film forming substance (for example, copper); and the substrate 106 is a member to be film-deposited on which the film forming substance is deposited.

The film deposition apparatus of the embodiment configured as described above performs the following operations, for example.

First, gas cluster ions generated by the gas gas cluster ion source 101 are transported as gas cluster ions having the same energy by the action of the set of electrodes for extraction, acceleration and focusing 102, and then enter the transverse field mass separator 103.

The transverse field mass separator 103 imparts an electric field and a magnetic field to the ion beam. When the electric field intensity E and the magnetic flux density B are set at a level of not deflecting gas cluster ions of 15 eV/(atom or molecule), gas cluster ions of 15 eV/(atom or molecule) go straight along an optical axis 110; gas cluster ions (108) having an energy of less than 15 eV/(atom or molecule) are deflected toward the substrate 106; and gas cluster ions (107) having an energy of more than 15 eV/(atom or molecule) are deflected toward the target 105.

Gas cluster ions having an energy of 10 eV to 5 keV per atom (or per molecule) are suitable for sputtering; and gas cluster ions having an energy of 0.01 eV to 20 eV per atom (or per molecule) are suitable for denseness and smoothness. This reveals that setting the energy of gas cluster ions irradiated to the substrate at a lower energy than that of gas cluster ions irradiated to the target allows an efficient and highly precise film deposition. “110 eV to 5 keV” unit not less than 10 eV and not more than 5 keV (the expression “to” unit the same in other descriptions).

The electric field intensity E and the magnetic flux density B are set so that gas cluster ions in the range of 10 eV/(atom or molecule) to 20 eV/(atom or molecule) are not deflected although they have an overlapping region because they have different suitable values depending on materials and other factors. By such a way, selection of clusters having a suitable energy becomes possible. Therefore, the precision of controlling the energies per atom (or molecule) of gas cluster ions 107, 108 directing to the target 105 and the substrate 106, respectively, can be enhanced, resulting in improving the controllability of the film deposition rate and the film quality.

Irradiation of gas cluster ions 107 on the target 105 causes sputtering on the target 105, and sputtered particles 109 containing a film forming substance are irradiated toward the substrate 106 and deposited on the substrate 106.

Impression of a minus bias voltage on the target 105 enhances the directivity of the gas cluster ions 107 in the vicinity of the target surface. It also enables the control of a center value of an energy distribution per atom (or molecule) of the gas cluster ions 107, making the film deposition rate more controllable.

Conversely, impression of a plus bias voltage on the target 105, since a blocking electric field acts on the gas cluster ions 107, enables the control of a center value of an energy distribution per atom (or molecule) of the gas cluster ions 107, making the film deposition rate more controllable.

The gas cluster ions 108 directed to the substrate 106 bombard the substrate simultaneously with deposition of the sputtered particles 109. In the embodiment, the gas cluster ions 108 do not damage the film since the energy per atom (or molecule) of the gas cluster ions 108 is as small as not more than 15 eV, about a threshold value of the energy to initiate sputtering, although depending on a material to be irradiated.

Moreover, since bombardment of clusters realizes a local high-temperature and high-pressure condition and induces migration of atoms constituting the film, the denseness and smoothness of the film is accomplished. To make the film uniform in thickness and quality across its plane, rotating and scanning of the substrate are effective. Simultaneously with deposition of sputtered particles and irradiation of gas cluster ions, electrons generated by the neutralizer 104 are irradiated on the substrate 106 and keep the surface of the substrate 106 electrically neutral.

According to the embodiment, since the gas cluster ion source can be unified, the cost of the apparatus can be reduced. Sizes of clusters suitable for sputtering and for flattening are different, respectively. Therefore, since the mass separation of clusters in different sizes generated by the gas cluster ion source allows clusters having sizes suitable for the target and the substrate to be irradiated thereon, the clusters can effectively be irradiated. A more specific example will be described hereinafter. In the embodiment, Ar pressurized at 0.5 MPa was used as a source gas of the gas cluster ion source 101, and adiabatically expanded into vacuum through a supersonic nozzle. A part of a jet flow thus obtained (φ2 mm of its center) was taken out using a skimmer, ionized by electron impact, then accelerated to 10 keV by the set of electrodes for extraction, acceleration and focusing 102, and made to go straight as gas cluster ions of 15 eV/Ar atom by the transverse field mass separator 103 set at E/B=8,500 (corresponding to 670 Ar atoms/cluster).

The target 105 used Cu, and a bias voltage of −130 V was impressed thereto. The neutralizer 104 was installed right above the substrate. The substrate 106 used a Si wafer, and a film was deposited while the substrate was being rotated at a speed of 10 rpm (This implies that the holding unit to hold the substrate 106 is adapted to be rotatable.).

According to the embodiment, the film deposition rate was 120 nm/min, and the surface of a Cu film had a 0.9-nm Ra. By the observation of the cross-section of the film by SEM, not a columnar structure found in ordinary sputtering film deposition, but a dense texture was found.

### Second Embodiment

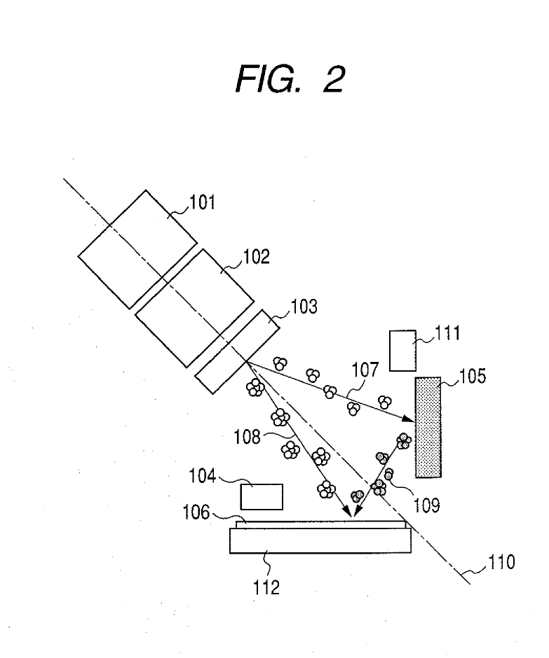

The present invention is not limited to the above-mentioned embodiment, and various changes and modifications are possible. Hereinafter, this will be described referring to FIG. 2.

A film deposition apparatus of is FIG. 2 is a modified system produced by a partial change in configuration of the film deposition apparatus of FIG. 1, and has different points that a neutralizer 111 is installed also in the vicinity of a target 105, not only in the vicinity of a substrate 106, and that a bias is not impressed on the target 105. By thus installing the neutralizers 104, 111 to supply electrons, the charge-up of the target 105 and the substrate 106 are prevented. The configuration of FIG. 2 is one in which an insulating material is sputtered instead of a conductive material.

A more specific example will be described hereinafter. In the embodiment, oxygen (O₂) pressurized at 0.8 MPa was used as a source gas of the gas cluster ion source 101, and adiabatically expanded into vacuum through a supersonic nozzle. A part of a jet flow thus obtained (φ2 mm of its center) was taken out using a skimmer, ionized by electron impact, then accelerated to 10 keV by the set of electrodes for extraction, acceleration and focusing 102, and made to go straight as gas cluster ions of 15 eV/oxygen molecule by the transverse field mass separator 103 set at E/B=9,480 (corresponding to 670 oxygen molecules/cluster).

The target 105 used SiO₂. The substrate 106 used a Si wafer, and a film was deposited while the substrate was being rotated at a speed of 10 rpm.

According to the embodiment, the film deposition rate was 60 nm/min, and the surface of a SiO₂ film had a 0.7-nm Ra. By the observation of the cross-section of the film by SEM, not a columnar structure found in ordinary sputtering film deposition, but a dense texture was found.

Although oxygen was used as a source gas in the above example, a rare gas such as He, Ar, Kr, or Xe may be added.

### Third Embodiment

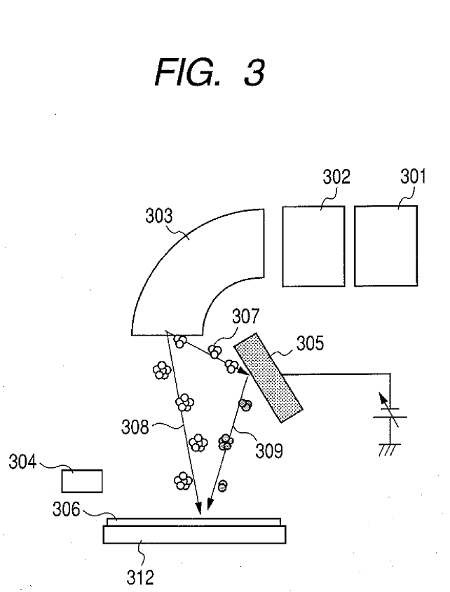

A film deposition apparatus of the present invention may be one shown in FIG. 3. The film deposition apparatus of FIG. 3 has ion beam irradiation unit composed of a gas cluster ion source 301, a set of electrodes for extraction, acceleration and focusing 302 and mass separating unit 303, and a neutralizer 304, as the apparatus of the first embodiment (see FIG. 1). It also has a target 305 equipped with a bias voltage impressing mechanism, a substrate 306 and holding unit 312 of the substrate 306. The different point from the configuration of the apparatus of FIG. 1 is that a fan-shaped permanent magnet 303 to form a fan-shaped beam path is installed as mass separation unit in place of the transverse field mass separator 103. The fan-shaped permanent magnet enlarges the apparatus volume, but has a simple and easily handleable structure. An example of the operation of the film deposition apparatus shown in FIG. 3 is as follows.

Gas cluster ions generated by the gas cluster ion source 301 are transported as gas cluster ions having the same energy by the action of the set of electrodes for extraction, acceleration and focusing 302 and then enter the fan-shaped permanent magnet 303.

In the fan-shaped permanent magnet 303, a magnetic field is imparted to the ion beam. By this, for example, gas cluster ions 307 having an energy exceeding 10 eV/(atom or molecule) are deflected toward the target, and gas cluster ions 308 having an energy of less than 10 eV/(atom or molecule) are deflected toward the substrate 306.

As described before, gas cluster ions having an energy per atom (or molecule) of 10 eV to 5 keV are suitable for sputtering, and gas cluster ions having an energy per atom (or molecule) of 0.01 eV to 20 eV are suitable for denseness and smoothness.

The electric field intensity E and the magnetic flux density B are set so that gas cluster ions in the range of 10 eV/(atom or molecule) to 20 eV/(atom or molecule) are not deflected although they have an overlapping region because they have different suitable values depending on materials and other factors. By such a way, selection of clusters having a suitable energy for the material becomes possible. Therefore, the precision of controlling the energies per atom (or molecule) of gas cluster ions 307, 308 directing to the target 305 and the substrate 306, respectively, can be enhanced, resulting in improving the controllability of the film deposition rate and the film quality.

Irradiation of gas cluster ions 307 on the target 305 causes sputtering on the target 305, and sputtered particles 309 containing a film forming substance are irradiated toward the substrate 306 and deposited on the substrate 306.

Impression of a minus bias voltage on the target 305 enhances the directivity of the gas cluster ions 307 in the vicinity of the target surface. It also enables the control of a center value of an energy distribution per atom (or molecule) of the gas cluster ions 307, making the film deposition rate more controllable.

Conversely, impression of a plus bias voltage on the target 305, since a blocking electric field acts on the gas cluster ions 307, enables the control of a center value of an energy distribution per atom (or molecule) of the gas cluster ions 307, making the film deposition rate more controllable.

On the other hand, gas cluster ions 308 directed to the substrate 306 bombard the substrate simultaneously with deposition of sputtered particles 309. In the embodiment, the gas cluster ions do not damage the deposit since the energy per atom (or molecule) thereof is as small as not more than 10 eV, about a threshold value of the energy to initiate sputtering, although depending on a material to be irradiated.

Moreover, since bombardment of clusters realizes a local high-temperature and high-pressure condition and induces migration of atoms constituting the film, the denseness and smoothness of the film is accomplished. As in the first embodiment, to make the film uniform in thickness and quality across its plane, rotating and scanning of the substrate are effective. Simultaneously with deposition of sputtered particles and irradiation of gas cluster ions, electrons generated by the neutralizer 304 are irradiated on the substrate 306 and keep the surface of the substrate 306 electrically neutral. The neutralizer 304 is an electron source composed of a heat filament, a hollow cathode, etc. as in the first embodiment.

A more specific example will be described hereinafter. In the embodiment, as in the first embodiment, Ar pressurized at 0.5 MPa was used as a source gas of the gas cluster ion source 301, and adiabatically expanded into vacuum through a supersonic nozzle. A part of a jet flow thus obtained (φ2 mm of its center) was taken out using a skimmer, ionized by electron impact, then accelerated to 10 keV by the set of electrodes for extraction, acceleration and focusing 302. The mass separation of the Ar cluster ions was performed using the fan-shaped permanent magnet of a magnetic flux density of 1 T.

As in the first embodiment, the target used Cu, and a bias voltage of −130 V was impressed thereto. The neutralizer 304 was installed right above the substrate. The substrate 306 used a Si wafer, and a film was deposited while the substrate was being rotated at a speed of 10 rpm.

According to the embodiment, the film deposition rate was 130 nm/min, and the surface of the Cu film had a 1.1-nm Ra. By the observation of the cross-section of the film by SEM, not a columnar structure found in ordinary sputtering film deposition, but a dense texture was found.

A fan-shaped permanent magnet was used as the mass separator 307 in the embodiment, but a mass separator composed of an electromagnet may be used in place of a permanent magnet.

### Fourth Embodiment

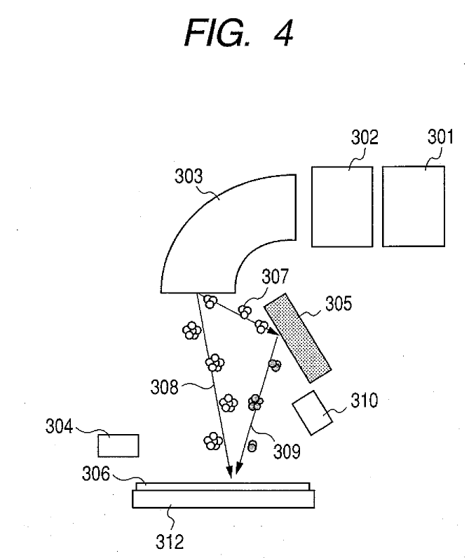

For a film deposition apparatus of the present invention, the configuration of the above third embodiment and the second embodiment can be combined. This will be described referring to FIG. 4 hereinafter.

The film deposition apparatus of FIG. 4 is a modified system produced by a partial change in configuration of the film deposition apparatus of FIG. 3, and has different points that a neutralizer 310 is installed also in the vicinity of a target 305, not only in the vicinity of a substrate 306, and that a bias is not impressed on the target 305. The neutralizers 304, 310 are installed as described above to supply electrons, thereby preventing the charge-up of the target 305 and the substrate 306. The configuration of FIG. 4 is adapted to sputter an insulating material.

A more specific example will be described hereinafter. In the embodiment, as in the second embodiment, oxygen pressurized at 0.8 MPa was used as a source gas of the gas cluster ion source 301, and adiabatically expanded into vacuum through a supersonic nozzle. A part of a jet flow thus obtained (φ2 mm of its center) was taken out using a skimmer, ionized by electron impact, then accelerated to 10 keV by the set of electrodes for extraction, acceleration and focusing 302. The mass separation of the oxygen cluster ions was performed using a fan-shaped permanent magnet of a magnetic flux density of 1 T. The target used SiO₂ as in the second embodiment. The substrate 306 used a Si wafer, and a film was deposited while the substrate was being rotated at a speed of 10 rpm.

According to the embodiment, the film deposition rate was 75 nm/min, and the surface of the SiO₂ film had a 0.8-nm Ra. By the observation of the cross-section of the film by SEM, not a columnar structure found in ordinary sputtering film deposition, but a dense texture was found.

### Fifth Embodiment

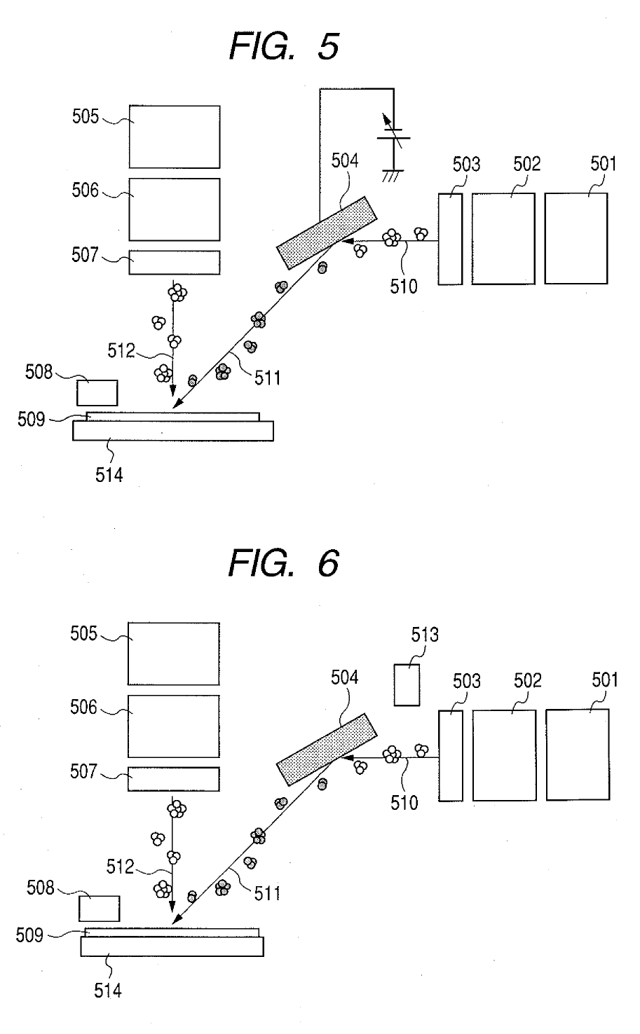

In the above-mentioned embodiments, the configurations were described in which a single gas cluster ion source (see reference numeral 101 of FIG. 1, reference numeral 301 of FIG. 3, etc.) is installed, but the present invention is not limited thereto. Hereinafter, this will be described referring to FIG. 5.

The film deposition apparatus of FIG. 5 has, as ion sources, two of a gas cluster ion source 501 for sputtering (a first gas cluster ion source) and a gas cluster ion source 505 for assist (a second gas cluster ion source). The structures of the circumferences of the ion sources 501, 502 have the similar one.

That is, as ion beam irradiation unit of the embodiment, sets of electrodes for extraction, acceleration and focusing 502, 506 are arranged slightly downstream of (downstream in the beam irradiation direction) and adjacent to the ion sources 501, 505, respectively. Further, permanent magnets 503, 507 are arranged adjacent to the sets of electrodes 502, 506, respectively. The ion beam irradiation unit has such a configuration.

Below the permanent magnet 507, a substrate 509 held on holding unit 514 is arranged, and a neutralizer 508 is arranged in the vicinity of the substrate 509. An example of the operation of the film deposition apparatus shown in FIG. 5 is as follows.

Gas cluster ions generated by the ion sources 501, 505 are transported as gas cluster ions having the same energy by the action of the sets of electrodes 502, 506, and enter the permanent magnets 503, 507, respectively. Gas cluster ions directed to a target 504 are accelerated to 10 eV to 100 keV; and those directed to the substrate 509 are accelerated to not more than 10 keV.

The permanent magnet 503 removes gas cluster ions having an energy per atom (or molecule) of not less than 5 keV out of the ion beam. On the other hand, the permanent magnet 507 removes gas cluster ions having an energy per atom (or molecule) of not less than 10 eV out of the ion beam. Gas cluster ions 510, 512 thus adjusted are irradiated on the target 504 and the substrate 509, respectively. In the embodiment, the damage of the film caused by the bombardment of high-speed assist particles and high-speed ions reflected from the target on the film deposition surface and the ion implantation to the target, are prevented.

The gas cluster ions 510 directed to the target 504, as in the first embodiment, bombard the target 504 to cause sputtering and sputtered particles 511 containing a film deposition material are deposited on the substrate 509.

Impression of a minus bias voltage on the target 504 enhances the directivity of the gas cluster ions 510 in the vicinity of the target surface. It also enables the control of a center value of an energy distribution per atom (or molecule) of the gas cluster ions 510, making the film deposition rate more controllable. Conversely, impression of a positive bias voltage on the target 504 enables the control of a center value of an energy distribution per atom (or molecule) of the gas cluster ions 510 because a blocking electric field acts on the gas cluster ions 510, making the film deposition rate more controllable.

On the other hand, the gas cluster ions 512 directed to the substrate 509 bombard the substrate simultaneously with the deposition of sputtered particles 511. In the embodiment, since the energy per atom (or molecule) is as small as not more than 10 eV, about a threshold value of the energy to initiate sputtering, although depending on the material to be irradiated, the film is not damaged.

Moreover, since bombardment of clusters realizes a local high-temperature and high-pressure condition and induces migration of atoms constituting the film, the denseness and smoothness of the film is accomplished. As in the first embodiment, to make the film uniform in thickness and quality across its plane, rotating and scanning of the substrate are effective. Simultaneously with deposition of sputtered particles and irradiation of gas cluster ions, electrons generated by the neutralizer 508 are irradiated on the substrate 509 and keep the surface of the substrate 509 electrically neutral.

Installing both a gas cluster ion source for irradiation on a target for sputtering and a gas cluster ion source for assist for irradiation on a substrate to promote denseness and smoothness enables a highly effective film deposition. Since gas cluster ions having sizes suitable for sputtering or flattening can be independently controlled and generated, gas cluster ions in sizes aimed at can effectively be generated, and the controllability of gas cluster ions is raised, allowing a highly efficient film deposition.

Although the configuration using two ion sources was described in the embodiment, preparing a plurality of gas cluster ion sources for assist to promote the reaction is possible.

A more specific example will be described hereinafter. In the embodiment, as in the first embodiment, Ar pressurized at 0.5 MPa was used as a source gas of the gas cluster ion source 501, and adiabatically expanded into vacuum through a supersonic nozzle. A part of a jet flow thus obtained (φ2 mm of its center) was taken out using a skimmer, ionized by electron impact, and then accelerated to 45 keV by the set of electrodes for extraction, acceleration and focusing. Then, gas cluster ions having not more than 10 atoms were deviated from the trajectories toward the Cu target by the permanent magnet.

The target 504 used Cu, and a bias voltage of −150 V was impressed thereon. Ar pressurized at 0.7 MPa was used as a source gas of the gas cluster ion source for assist, and adiabatically expanded into vacuum through a supersonic nozzle. As described above, a part of a jet flow thus obtained (φ2 mm of its center) was taken out using a skimmer, ionized by electron impact, and then accelerated to 3 keV by the set of electrodes for extraction, acceleration and focusing. Then, gas cluster ions having not more than 300 atoms were deviated from the trajectories toward the substrate by the permanent magnet. The substrate 509 used a Si wafer, and the film was deposited while the substrate was being rotated at a speed of 10 rpm.

According to the embodiment, the film deposition rate was 250 nm/min, and the surface of the Cu film had a 0.8-nm Ra. By the observation of the cross-section of the film by SEM, not a columnar structure found in ordinary sputtering film deposition, but a dense texture was found.

Although permanent magnets were used as the mass separators in the embodiment, any of permanent magnets, electromagnets, transverse field mass separators, deceleration field mass separators, radio-frequency deflection mass separators, radio-frequency acceleration mass separators, time-of-flight mass separators and quadrupole mass separators may be used. The mass separator is one which deflects the trajectories of gas cluster ions according to the mass thereof and makes gas cluster ions having a mass of not less than a desired one to pass through. The mass separator removes high-speed, high-energy particles out of particles which reflect from a target or are incident directly on a substrate.

For example, the mass separator removes particles having a size of not more than 10 atoms (or 10 molecules) per cluster. Of course, these mass filters may be used in an optional combination.

### Sixth Embodiment

For the film deposition apparatus of the present invention, the above-mentioned fifth embodiment can be further changed. This will be described referring to FIG. 6 hereinafter.

The film deposition apparatus of FIG. 6 is a modified system produced by a partial change in configuration of the film deposition apparatus of FIG. 5. The major different points from the film deposition apparatus of FIG. 5 are that a neutralizer 513 is installed also in the vicinity of a target 504, not only in the vicinity of a substrate 509, and that a bias is not impressed on the target 504.

A more specific example will be described hereinafter. In the embodiment, as in the first embodiment, Ar pressurized at 0.5 MPa was used as a source gas of the gas cluster ion source 501 for sputtering, and adiabatically expanded into vacuum through a supersonic nozzle. A part of a jet flow thus obtained (φ2 mm of its center) was taken out using a skimmer, ionized by electron impact, and then accelerated to 45 keV by a set of electrodes for extraction, acceleration and focusing. Then, gas cluster ions having not more than 10 atoms were deviated from the trajectories toward the SiO₂ target by a permanent magnet.

On the other hand, oxygen pressurized at 0.9 MPa was used as a source gas of the gas cluster ion source for assist, and adiabatically expanded into vacuum through a supersonic nozzle. A part of a jet flow thus obtained (φ2 mm of its center) was taken out using a skimmer, ionized by electron impact, and then accelerated to 2 keV by a set of electrodes for extraction, acceleration and focusing. Then, gas cluster ions having not more than 200 atoms were deviated from the trajectories toward the substrate by a permanent magnet. The substrate used a Si wafer, and the film was deposited while the substrate was being rotated at a speed of 10 rpm.

According to the embodiment, the film deposition rate was 120 nm/min, and the surface of the SiO₂ film had a 0.5-nm Ra. By the observation of the cross-section of the film by SEM, not a columnar structure found in ordinary sputtering film deposition, but a dense texture was found.

### Seventh Embodiment

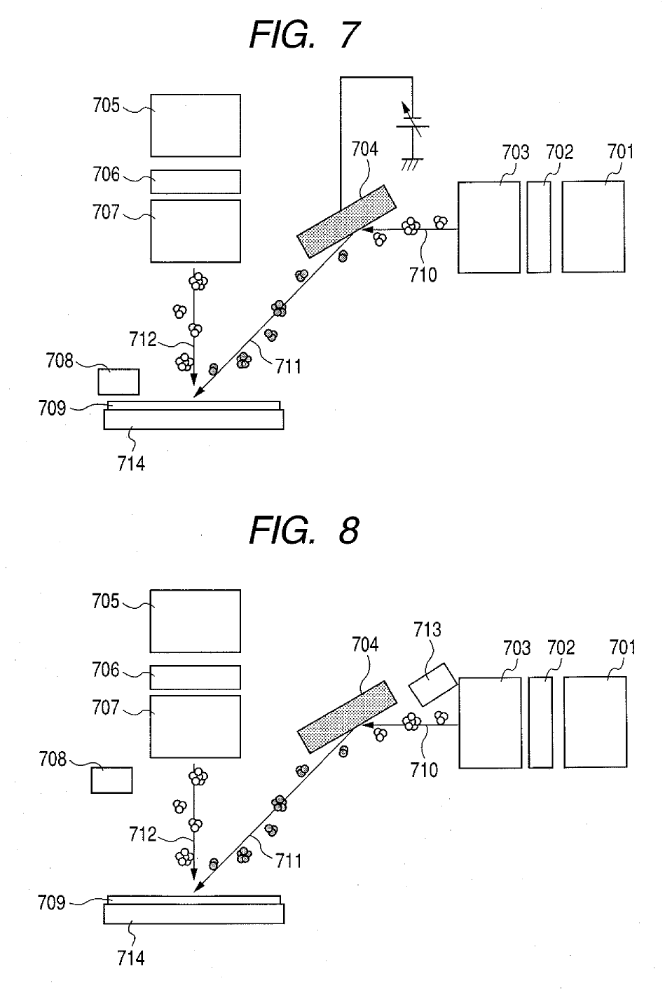

A film deposition apparatus of the present invention may be one as shown in FIG. 7.

The film deposition apparatus of FIG. 7 has a gas cluster ion source 701 for sputtering, a deceleration electrode 702 and a set of electrodes for extraction, acceleration and focusing 703. It also has a gas cluster ion source 705 for assist, a deceleration electrode 706 and a set of electrodes for extraction, acceleration and focusing 707. A neutralizer 708, a substrate 709 and its holding unit 714 are provided as in the above-mentioned embodiments.

The deceleration electrodes 702, 706 have a function of removing gas cluster ions having masses of not more than desired ones out of gas cluster ions generated by the ion sources 701, 705, respectively. The principle of such a deceleration field mass separator is disclosed in, for example, I. Yamada et al., Mater. Sci. Eng. R34 (2001) 231 and Japanese Patent Application Laid-Open No. H08-104980.

Out of gas cluster ions generated by the gas cluster ion sources 701, 705 for sputtering and for assist, gas cluster ions having masses of not more than desired ones are removed by the deceleration electrodes 702, 706, respectively. Gas cluster ions separated by mass are transported as gas cluster ions having the same energy by the action of the respective sets of electrodes for extraction, acceleration and focusing 703, 707. Gas cluster ions directed to the target 704 are accelerated to 10 to 100 keV, and gas cluster ions directed to the substrate 709 are accelerated to not more than 10 keV.

As in the embodiments, the gas cluster ions 710 bombard the target and cause sputtering, and sputtered particles 711 are deposited on the substrate 709. When a minus bias voltage is impressed on the target, the directivity of the gas cluster ions 710 is enhanced. The center value of an energy distribution per atom (or molecule) of the gas cluster ions 710 comes to be controlled, also making the film deposition rate more controllable as in the above-mentioned embodiments.

When a positive bias voltage is impressed on the target, since a blocking electric field acts on the gas cluster ions 710, the center value of an energy distribution per atom (or molecule) of the gas cluster ions 710 comes to be controlled, making the film deposition rate more controllable.

On the other hand, the gas cluster ions 712 directed to the substrate bombard the substrate simultaneously with deposition of the sputtered particles 711. In the embodiment, since the energy per atom (or molecule) is as small as not more than 10 eV, about a threshold value of the energy to initiate sputtering, although depending on the material to be irradiated, the film is not damaged.

Moreover, since bombardment of clusters realizes a local high-temperature and high-pressure condition and induces migration of atoms constituting the film, the denseness and smoothness of the film is accomplished. As in the first embodiment, to make the film uniform in thickness and quality across its plane, rotating and scanning of the substrate are effective. Simultaneously with deposition of sputtered particles and irradiation of gas cluster ions, electrons generated by the neutralizer 708 are irradiated on the substrate 709 and keep the surface of the substrate 709 electrically neutral.

A more specific example will be described hereinafter. In the embodiment, as in the first embodiment, Ar pressurized at 0.5 MPa was used as a source gas of the gas cluster ion source for sputtering, and adiabatically expanded into vacuum through a supersonic nozzle. A part of a jet flow thus obtained (φ2 mm of its center) was taken out using a skimmer, and ionized by electron impact. Thereafter, gas cluster ions having not more than 500 atoms were removed by making gas cluster ions pass through the deceleration electrode on which a voltage of 30 V was impressed, and the gas cluster ions having passed were accelerated to 50 keV by the set of electrodes for extraction, acceleration and focusing. The target 704 used Cu, and a bias voltage of −150 V was impressed.

Ar pressurized at 0.7 MPa was used as a source gas of the gas cluster ion source for assist, and adiabatically expanded into vacuum through a supersonic nozzle. A part of a jet flow thus obtained (φ2 mm of its center) was taken out using a skimmer, and ionized by electron impact. Thereafter, gas cluster ions having not more than 300 atoms were removed by making gas cluster ions pass through the deceleration electrode on which a voltage of 20 V was impressed, and the gas cluster ions having passed were accelerated to 3 keV by the set of electrodes for extraction, acceleration and focusing. The neutralizer was installed right above the substrate. The substrate used a Si wafer, and the film was deposited while the substrate was being rotated at a speed of 10 rpm.

According to the embodiment, the film deposition rate was 200 nm/min, and the surface of the Cu film had a 0.8-nm Ra. By the observation of the cross-section of the film by SEM, not a columnar structure found in ordinary sputtering film deposition, but a dense texture was found.

### Eighth Embodiment

A film deposition apparatus of the present invention may further be one as shown in FIG. 8.

The film deposition apparatus of FIG. 8 is a modified system produced by a partial change in configuration of the film deposition apparatus of FIG. 7. The major different points from the film deposition apparatus of FIG. 7 are that a neutralizer 713 is installed also in the vicinity of a target 704, not only in the vicinity of a substrate 709, and that a bias is not impressed on the target 704. The configuration of FIG. 8 involves sputtering an insulating material.

In the embodiment, Ar pressurized at 0.5 MPa was used as a source gas of the gas cluster ion source for sputtering, and adiabatically expanded into vacuum through a supersonic nozzle. A part of a jet flow thus obtained (φ2 mm of its center) was taken out using a skimmer, and ionized by electron impact. Thereafter, gas cluster ions having not more than 500 atoms were removed by making gas cluster ions pass through the deceleration electrode on which a voltage of 30 V was impressed, and the gas cluster ions having passed were accelerated to 50 keV by the set of electrodes for extraction, acceleration and focusing.

On the other hand, oxygen pressurized at 0.9 MPa was used as a source gas of the gas cluster ion source for assist, and adiabatically expanded into vacuum through a supersonic nozzle. A part of a jet flow thus obtained (φ2 mm of its center) was taken out using a skimmer, and ionized by electron impact. Thereafter, gas cluster ions having not more than 200 molecules were removed by making gas cluster ions pass through the deceleration electrode on which a voltage of 20 V was impressed, and the gas cluster ions having passed were accelerated to 2 keV by the set of electrodes for extraction, acceleration and focusing. The substrate used a Si wafer, and the film was deposited while the substrate was being rotated at a speed of 10 rpm.

According to the embodiment, the film deposition rate was 90 nm/min, and the surface of the SiO₂ film had a 0.5-nm Ra. By the observation of the cross-section of the film by SEM, not a columnar structure found in ordinary sputtering film deposition, but a dense texture was found.

Hereinbefore, the present invention has been described exemplifying the several embodiments (specifically, centered on the film deposition apparatuses), but the present invention can be construed to be an invention relevant to a method. That is, the method of film deposition of the present invention involves forming a film on a substrate surface by irradiating sputtered particles generated by sputtering of a target toward the substrate surface, and includes a step of irradiating gas gas cluster ions against the target. Thereby, the target is sputtered, and the resultantly generated sputtered particles are deposited as a film on the substrate.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application Nos. 2006-074515, filed Mar. 17, 2006 and 2007-049179, filed Feb. 28, 2007, which are hereby incorporated by reference herein in its entirety.

1. A film deposition apparatus for deposition of a film forming substance on a substrate, comprising:
ion beam irradiating unit;
a target comprising the film forming substance to be sputtered; and
holding unit to hold the substrate on which the sputtered film forming substance is deposited,
wherein the ion beam irradiation unit irradiates gas cluster ions to both the target and the substrate.

2. The film deposition apparatus according to claim 1, characterized in that the ion beam irradiation unit has mass separating unit to deflect the trajectories of the gas cluster ions generated by a gas cluster ion source according to masses of the gas cluster ions and irradiate the gas cluster ions having a different energy to each of the target and the substrate.

3. The film deposition apparatus according to claim 2, characterized in that the gas cluster ions irradiated to the substrate have a lower energy than the gas cluster ions irradiated to the target.

4. The film deposition apparatus according to claim 1, characterized in that the mass separating unit comprises at least one selected from permanent magnets, electromagnets and transverse field mass separators.

5. The film deposition apparatus according to claim 1, characterized by further comprising unit to impress a bias on the target.

6. The film deposition apparatus according to claim 1, characterized by further comprising a neutralizer to irradiate electrons toward the target and/or the substrate.

7. A film deposition apparatus for deposition of a film forming substance on a substrate, comprising:
a target comprising the film forming substance to be sputtered;
holding unit to hold the substrate on which the sputtered film forming substance is deposited; and
a plurality of gas cluster ion sources,
wherein gas cluster ions generated by a first gas cluster ion source are irradiated to the target, and gas cluster ions generated by a second gas cluster ion source are irradiated to the substrate.

8. The film deposition apparatus according to claim 7, characterized in that the gas cluster ions irradiated to the substrate have an energy per atom or molecule in the range of not less than 0.01 eV and not more than 20 eV, and the gas cluster ions irradiated to the target have an energy per atom or molecule in the range of not less than 10 eV and not more than 5 keV.

9. A film deposition method for deposition of a film forming substance on a substrate using a film deposition apparatus,
the film deposition apparatus comprising a target, holding unit to hold the substrate and one or more ion beam irradiating unit to irradiate gas cluster ions,
the method comprising:
irradiating the gas cluster ions to the target to generate sputtered particles comprising the film forming substance;
depositing the film forming substance on the substrate; and
irradiating the gas cluster ions to the substrate.

10. The method of film deposition according to claim 9, characterized in that the gas cluster ions irradiated to the substrate have a lower energy than the gas cluster ions irradiated to the target.
